(19) United States
(12) Patent Application Publication
(10) Pub. No.: US 2007/0087503 A1
(43) Pub. Date: Apr. 19, 2007

(54) Improving NROM device characteristics using adjusted gate work function

(75) Inventor: Eli Lusky, Tel Aviv (IL)

Correspondence Address: Eitan Law Group;C/O LandonIP Inc., 1700 Diagonal Road, Suite 450, Alexandria, VA, 22314, US

(73) Assignee: Saifun Semiconductors, Ltd., Netanya (IL)

(21) Appl. No.: 11/253,272

(22) Filed: Oct. 17, 2005

(51) Int. Cl. H01L 21/336

(52) U.S. Cl. 438/257

(57) ABSTRACT

A method including adjusting a threshold voltage of an NROM (nitride, read only memory) device by adjusting a work function associated with a gate terminal of the NROM device.

### FIELD OF THE INVENTION

The present invention relates to NROM devices, and more particularly to improving reliability and electrical characteristics of such devices by adjusting a gate work function during fabrication of the devices.

### BACKGROUND OF THE INVENTION

Non-volatile memory (NVM) cells are designed to store information for long periods of time. For floating gate technology, this means charge should be retained for as long as possible on the floating gate, that is, retention loss should be kept as low as possible.

Another type of non-volatile cell is a nitride, read only memory (NROM) cell. Unlike a floating gate cell, the NROM cell has two separately chargeable areas. Each chargeable area may define one bit or more. The separately chargeable areas are found within a nitride layer formed in an oxide-nitride-oxide (ONO) stack underneath the gate. When programming a bit, channel hot electrons (CHE) are injected into the nitride layer. This is generally accomplished by the application of a positive gate voltage and positive drain voltage, the magnitude and duration of which are determined by different factors related to the amount of programming required. It is noted that in NROM cells, programmed bits in the charge-trapping nitride layer are generally erased by hot hole injection (HHI) and not by Fowler-Nordheim (FN) tunneling.

As is well known in the art, the work function of the gate terminal in n-channel and p-channel metal oxide semiconductor field effect transistors (NMOSFET and PMOSFET, respectively) may be modified by doping the polysilicon gate with phosphorus and boron dopants, respectively, in order to decrease the transistor's threshold voltage (V_{T}) and to avoid buried channel conductance.

Since NROM is an n-channel transistor, doing the opposite is of benefit in NROM structure, i.e., increasing V_{T} by boron implant. Typically, the target V_{T} in NROM is ˜1.5-2V compared to ˜0.3-0.7V in NMOSFET. The elevated V_{T} in NROM is an outcome of the scaling requirements of NROM technology in terms of channel length and electrical characteristics, e.g., mainly surface punchthrough leakage and erase operation. Typically, both requirements are achieved by increasing the channel doping. NROM devices may typically include P+ pocket implants (e.g., boron, indium or others) for channel doping.

Accordingly, as opposed to standard CMOS devices, doping the NROM polysilicon gate by boron implanting increases the NROM V_{T}, thus preventing channel surface punchthrough leakage without the need for increased channel doping. Moreover, it has been found that an NROM cell is better optimized with reduced channel doping, since retention loss decreases and junction breakdown voltage increases.

Both reduced retention loss and increased BL breakdown voltage are desired for long retaining time, e.g., 10 years, of stored data and for improved performance, e.g., high bit line voltages.

To avoid subsurface punchthrough leakage associated with buried channel conductance as is typical in PMOSFET with a phosphorous doped polysilicon gate, a pocket implant may be implemented as well (see, e.g., A. Hori et al., “A Self-Aligned Pocket Implantation Technology for 0.2 um Dual-Gate CMOS”, IEEE EDL, Vol. 13, No. 4 April 1992, p.174).

FIG. 1 illustrates an example of the retention loss changing as a function of the channel doping concentration. The graph illustrates program margin versus bake time for two cases of low and high channel doping following cycling. By examining FIG. 1 it may be seen that the retention loss may increase by ˜100-300 mV due to increased channel doping concentration.

As is well known in the art, bits stored in NVM cells may be read by means of a sense amplifier that determines the logical value stored in the cell by comparing the output of the cell with a reference level. If the current output is above the reference the cell is considered erased, and if the current output is below the reference the cell is considered programmed. Typically, a sufficient difference is defined between the expected erased and programmed voltage levels so that noise on the output will not cause false results. Accordingly, a program verify (PV) reference level and an erase verify (EV) reference level may be defined with a sufficient margin therebetween. The margin may help maintain the same reading for the programmed or erased state of the cell. However, the margin may change due to retention loss (among other things). Thus, as FIG. 1 shows, the higher doping concentration reduces the program margin, which means the retention loss increases, as mentioned above.

Doping concentration also affects bit line (BL) breakdown voltage. Referring to FIG. 2, it may be seen that for optimized cells with n+ (phosphorus) vs. p+ like (boron) doping of the polysilicon gate, the breakdown voltage of the junction is expected to differ due to the associated channel doping. For example; the breakdown voltage is approximately 6.8V for high channel doping concentration (n+ doping of the polysilicon gate) as opposed to approximately 7.3V for low channel doping concentration (p+ like doping of the polysilicon gate).

It is noted that the work function has been modified in the prior art. For example, U.S. Pat. No. 6,885,590 to Zheng et al., assigned to Advanced Micro Devices, Inc. (Sunnyvale, Calif.) describes a non-volatile memory device, which is SONOS (silicon/oxide-nitride-oxide on semiconductor). The device includes a silicon substrate and an N-type source and drain within the substrate. An oxide-nitride-oxide (ONO) stack is formed over the substrate. The ONO stack includes a thin bottom oxide layer. A P⁺ polysilicon electrode is formed over the ONO stack. Erasing the SONOS device is accomplished by Fowler-Nordheim (FN) tunneling, whereas programming is done with channel hot electron (CHE) injection. Thus in Zheng et al., the adjusted work function is used for forming a modified SONOS cell with CHE injection and FN erase. This is not applicable for the present invention, which is directed to NROM cells, which as mentioned above, are erased by hot hole injection and not by FN tunneling. Moreover, in SONOS devices, P+ polysilicon electrode is implemented in order to avoid electron injection from the gate electrode, an irrelevant consideration in NROM devices.

### SUMMARY OF THE INVENTION

The present invention seeks to provide methods for improving electrical characteristics of NVM devices (e.g., NROM) by adjusting a gate work function during fabrication of the devices.

There is provided in accordance with an embodiment of the present invention a method including adjusting a threshold voltage of an NROM device by adjusting a work function associated with a gate terminal of the NROM device.

In accordance with an embodiment of the present invention, the NROM device includes an NMOS transistor with an oxide-nitride-oxide gate dielectric used as a trapping medium, and wherein the NROM device is programmable by channel hot electron injection and erasable by hot hole injection.

In accordance with another embodiment of the present invention, the gate terminal includes a polysilicon layer, and adjusting the work function includes doping the polysilicon layer with a p-type dopant.

In accordance with another embodiment of the present invention, the gate terminal includes a metal layer, and adjusting the work function includes substituting one metal for another metal in the metal layer.

In accordance with another embodiment of the present invention, the gate terminal includes a metal layer, and adjusting the work function includes metallurgically changing the metal in the metal layer.

There is also provided in accordance with an embodiment of the present invention a method including improving reliability of an NROM device by adjusting a work function associated with a gate terminal of the NROM device so as to reduce the channel doping while maintaining the same threshold voltage of the NROM device.

In accordance with another embodiment of the present invention, decreasing the channel doping includes reducing at least one of a pocket implant dosage and pocket implant energy.

In accordance with another embodiment of the present invention, decreasing the channel doping includes reducing at least one of a cell well dose and cell well energy.

In accordance with another embodiment of the present invention, decreasing the channel doping decreases retention loss of the NROM device.

In accordance with another embodiment of the present invention, decreasing the channel doping increases the bit line breakdown voltage of the NROM device.

In accordance with another embodiment of the present invention, the work function is adjusted and the channel doping is reduced so that punchthrough leakage of the NROM device does not degrade.

In accordance with another embodiment of the present invention, the work function is adjusted and the channel doping is reduced so that a voltage needed for performing an erase operation on the NROM device does not increase.

In accordance with another embodiment of the present invention, the work function is adjusted and the channel doping is reduced so that a channel length Leff associated with the NROM device remains generally unchanged.

In accordance with another embodiment of the present invention, the work function is adjusted so as not to degrade electrical characteristics of the NROM device.

### BRIEF DESCRIPTION OF THE DRAWINGS

The present invention will be understood and appreciated more fully from the following detailed description taken in conjunction with the drawings in which:

FIG. 1 is a simplified graphical diagram of retention loss as a function of bake time for devices with different doping concentration;

FIG. 2 is a simplified graphical diagram of bit line (BL) breakdown voltage as a function of doping concentration;

FIG. 3 is a simplified illustration of a method for improving the reliability of an NROM device, in accordance with an embodiment of the present invention;

FIG. 4 is a simplified graphical diagram of threshold voltage vs. effective channel length associated with p+ doped polysilicon as opposed to prior art n+ doping;

FIG. 5 is a simplified graphical diagram of puncthrough voltage vs. effective channel length associated with p+ doped polysilicon as opposed to prior art n+ doping; and

FIG. 6 is a simplified graphical diagram of erase voltage vs. effective channel length associated with p+ doped polysilicon as opposed to prior art n+ doping.

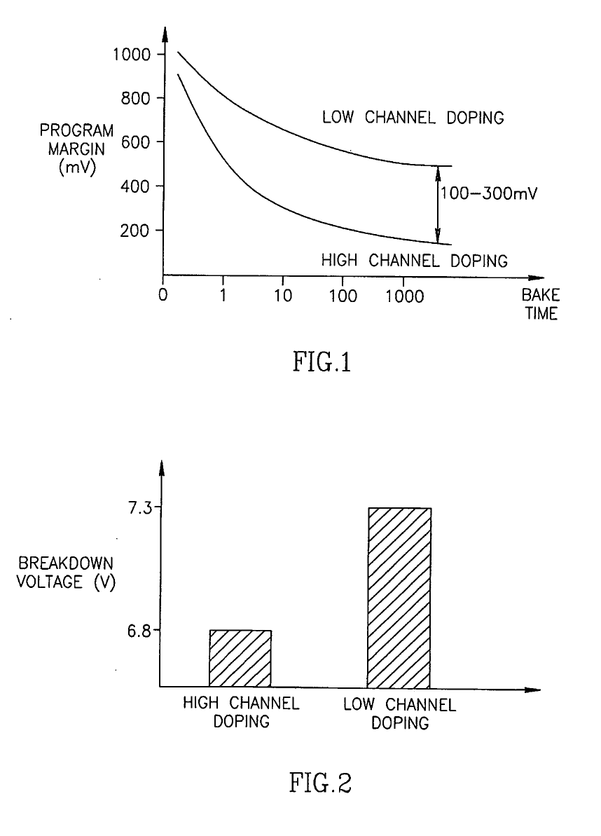

### DETAILED DESCRIPTION OF EMBODIMENTS

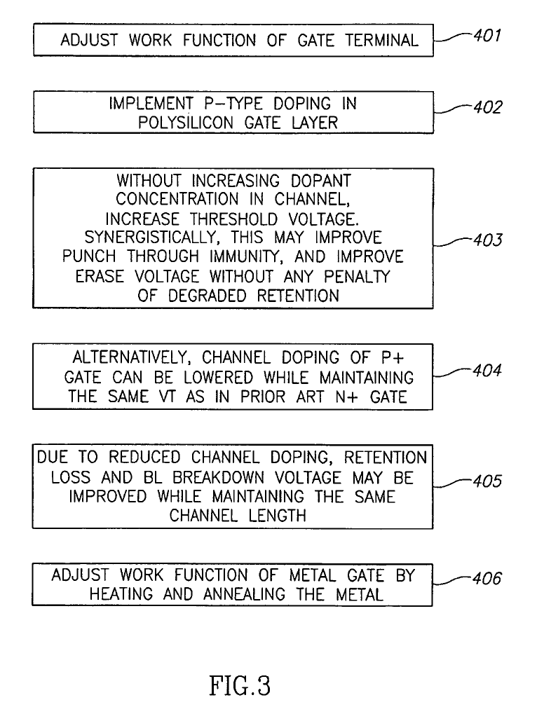

Reference is now made to FIG. 3, which illustrates a method for improving the reliability of an NROM device, in accordance with an embodiment of the present invention.

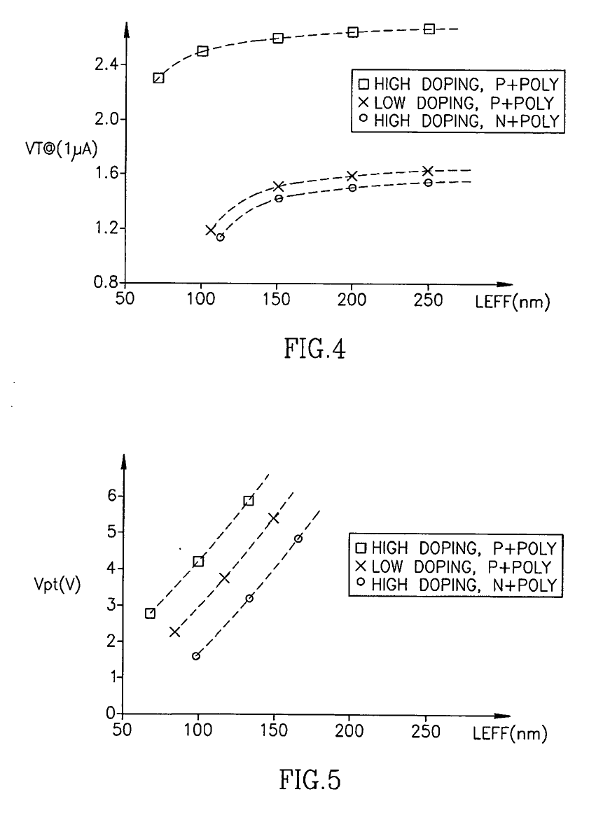

In one embodiment of the invention, the reliability may be improved by adjusting the work function of a gate terminal of the NROM device (box 401). In the prior art, NROM devices have used n-type doping (e.g., phosphorus) of the polysilicon gate. In contrast, in the present invention, p-type doping (e.g., boron) may be implemented in the polysilicon gate layer (box 402). Referring to FIG. 4, it may be seen that the threshold voltage Vt associated with the p+ doped polysilicon may be approximately 1V higher than the prior art n+ doping, for the same doping concentration Thus, in the present invention, without increasing the dopant concentration in the channel, the threshold voltage may be increased. Synergistically, this also may improve punchthrough immunity and improve erase voltage (i.e., lower the voltage needed for performing an erase operation) without any penalty of degraded retention (box 403).

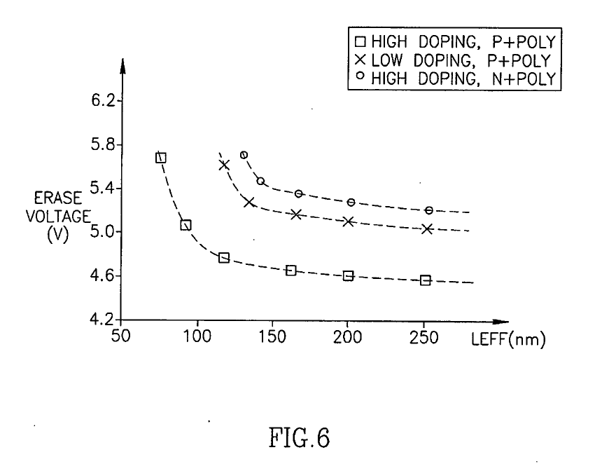

Further, in accordance with another embodiment of the invention, the p+ doped polysilicon gate cell may have lower channel doping than that of the prior art n+ doped NROM while maintaining the same Vt (box 404), thereby providing the benefits of higher bit line breakdown voltage and reduced retention loss. FIGS. 5 and 6 illustrate graphically the effect of channel doping as well as electrode type on the threshold voltage and erase voltage, respectively, as a function of the effective channel length (the graphs of FIGS. 4-6 do not present actually measured P+ vs. N+ silicon results, but rather expected results). It is seen that the V_{T} increases and the erase voltage decreases when either the doping channel increases or p+ gate electrode is selected. Thus, if reduced channel doping is implemented, retention loss may be reduced and bit line breakdown voltage may be increased while maintaining the same channel length Leff (box 405).

The present invention is not limited to adjusting the work function by doping polysilicon. The invention may also be carried out for metal gates. In such a case, adjusting the work function is generally not carried out by doping, but by other techniques. For example, without limitation, the work function of the metal gate may be adjusted by proper selection of the gate material and/or metallurgically changing the metal, such as by heating and annealing the metal (box 406). Changing the work function of a metal gate by annealing has been described by Exploit Technologies Private Limited (A member of A*STAR) 30 Biopolis Street, #09-02, Singapore) (www.exploit-tech .com/industries/semiconductors/IME05TOSE003 .htm).

It is also appreciated that various features of the invention which are, for clarity, described in the contexts of separate embodiments, may also be provided in combination in a single embodiment. Conversely, various features of the invention, which are, for brevity, described in the context of a single embodiment, may also be provided separately or in any suitable subcombination.

What is claimed is:

1. A method comprising:
adjusting a threshold voltage of an NROM (nitride, read only memory) device by adjusting a work function associated with a gate terminal of the NROM device.

2. The method according to claim 1, wherein the NROM device comprises an NMOS (n-channel metal oxide semniconductor) transistor with an oxide-nitride-oxide gate dielectric used as a trapping medium, and wherein said NROM device is programmable by channel hot electron injection and erasable by hot hole injection.

3. The method according to claim 1, wherein the gate terminal comprises a polysilicon layer, and adjusting the work function comprises doping the polysilicon layer with a p-type dopant.

4. The method according to claim 1, wherein the gate terminal comprises a metal layer, and adjusting the work function comprises substituting one metal for another metal in said metal layer.

5. The method according to claim 1, wherein the gate terminal comprises a metal layer, and adjusting the work function comprises metallurgically changing the metal in said metal layer.

6. A method comprising:
improving reliability and electrical characteristics of an NROM device by adjusting a work function associated with a gate terminal of the NROM device so as to reduce channel doping while maintaining same threshold voltage of said NROM device.

7. The method according to claim 6, wherein the NROM device comprises an NMOS transistor with an oxide-nitride-oxide gate dielectric used as a trapping medium, and wherein said NROM device is programmable by channel hot electron injection and erasable by hot hole injection.

8. The method according to claim 6, wherein the gate terminal comprises a polysilicon layer, and adjusting the work function comprises increasing the work function by doping the polysilicon layer with a p-type dopant.

9. The method according to claim 6, wherein the gate terminal comprises a metal layer, and adjusting the work function comprises substituting one metal for another metal in said metal layer.

10. The method according to claim 6, wherein the gate terminal comprises a metal layer, and adjusting the work function comprises metallurgically changing the metal in said metal layer.

11. The method according to claim 6, wherein decreasing the channel doping comprises reducing at least one of a pocket implant dosage and pocket implant energy.

12. The method according to claim 6, wherein decreasing the channel doping comprises reducing at least one of a cell well dose and cell well energy.

13. The method according to claim 6, wherein decreasing the channel doping decreases retention loss of the NROM device.

14. The method according to claim 6, wherein the work function is adjusted so that bit line breakdown voltage of the NROM device increases.

15. The method according to claim 6, wherein the work function is adjusted so that punchthrough leakage of the NROM device does not degrade.

16. The method according to claim 6, wherein the work function is adjusted so that a voltage needed for performing an erase operation on the NROM device does not increase.

17. The method according to claim 6, wherein the work function is adjusted so that a channel length Leff associated with the NROM device remains generally unchanged.

18. The method according to claim 6, wherein the work function is adjusted so as not to degrade electrical characteristics of the NROM device.
